(19) United States
(12) Patent Application Publication
(10) Pub. No.: US 2015/0137092 A1
(43) Pub. Date: May 21, 2015

(54) TRANSISTOR STRUCTURE AND MANUFACTURING METHOD THEREOF

(71) Applicant: E Ink Holdings Inc., Hsinchu (TW)

(72) Inventors: Cheng-Hang Hsu, Hsinchu (TW); Henry Wang, Hsinchu (TW); Chih-Hsuan Wang, Hsinchu (TW); Ted-Hong Shinn, Hsinchu (TW)

(21) Appl. No.: 14/476,753

(22) Filed: Sep. 4, 2014

(30) Foreign Application Priority Data
Nov. 21, 2013 (TW) 102142495

(51) Int. Cl. H01L 51/05; H01L 29/49

(52) U.S. Cl. CPC H01L 51/055; H01L 29/4908; H01L 29/495
USPC 257/40; 438/99

(57) ABSTRACT

A transistor structure disposed on a substrate includes a gate electrode, an organic semiconductor layer, a gate insulation layer and a patterned metal layer. The gate insulation layer is disposed between the gate and the organic semiconductor layer. The patterned metal layer has a conductive oxidation surface and is divided into a source electrode and a drain electrode. A portion of the organic semiconductor layer is exposed between the source electrode and the drain electrode. The conductive oxidation surface directly contacts with the organic semiconductor layer.

### CROSS-REFERENCE TO RELATED APPLICATION

This application claims the priority benefit of Taiwan application serial no. 102142495, filed on Nov. 21, 2013. The entirety of the above-mentioned patent application is hereby incorporated by reference herein and made a part of this specification.

### BACKGROUND OF THE INVENTION

1. Field of the Invention

The disclosure relates to a structure of a semiconductor structure and a manufacturing method thereof. More particularly, the disclosure relates to a transistor structure and a manufacturing method thereof.

2. Description of Related Art

Organic thin film transistors (OTFTs) have advantages of being able to be manufactured under low temperature, having simple processes, and being able to be made in large areas. Since semiconductor layers of the OTFTs are made by organic materials, metal electrodes with high work functions are required for carrier transmission. Metals having high work functions, such as gold, platinum, palladium or silver, cost high, and the fabrication process of the same are difficult.

### SUMMARY OF THE INVENTION

The disclosure provides a transistor structure having superior electrical performance and low cost.

The disclosure provides a method for manufacturing the aforementioned transistor structure.

A transistor structure of the disclosure is disposed on a substrate and includes a gate electrode, an organic semiconductor layer, a gate insulation layer and a patterned metal layer. The gate insulation layer is disposed between the gate and the organic semiconductor layer. The patterned metal layer has a conductive oxidation surface and is divided into a source electrode and a drain electrode. A portion of the organic semiconductor layer is exposed between the source electrode and the drain electrode. The conductive oxidation surface directly contacts with the organic semiconductor layer.

According to an embodiment of the disclosure, the source electrode and the drain electrode are disposed on the substrate and expose a portion of the substrate. The organic semiconductor layer is disposed on the source electrode and the drain electrode and covers the portion of the substrate. The gate insulation layer is disposed on the organic semiconductor layer and covers the organic semiconductor layer, the source electrode and the drain electrode. The gate is disposed on the gate insulation layer.

According to an embodiment of the disclosure, a material of the patterned metal layer includes molybdenum, chrome, aluminum, nickel, copper, or alloy of the same.

According to an embodiment of the disclosure, a thickness of the conductive oxidation surface ranges from 1 nm to 100 nm.

The disclosure further provides a method of manufacturing a transistor structure including the following steps. A surface treatment process is performed to a surface of a patterned metal layer, to form a conductive oxidation surface on the patterned metal layer. The patterned metal layer is divided into a source electrode and a drain electrode. A gate electrode, an organic semiconductor layer, and a gate insulation layer are formed. The gate insulation layer is disposed between the gate and the organic semiconductor layer. A portion of the organic semiconductor layer is exposed between the source electrode and the drain electrode. The conductive oxidation surface directly contacts with the organic semiconductor layer.

According to an embodiment of the disclosure, the aforementioned surface treatment process comprises an oxygen-containing plasma treatment process, an oxygen-containing heat treatment process, a chemical oxidation process or an electrochemical oxidation treatment process.

According to an embodiment of the disclosure, the source electrode and the drain electrode are formed on a substrate and expose a portion of the substrate. The organic semiconductor layer is formed on the source electrode and the drain electrode and covers the portion of the substrate. The gate insulation layer is formed on the organic semiconductor layer and covers the organic semiconductor layer, the source electrode and the drain electrode. The gate is formed on the gate insulation layer.

According to an embodiment of the disclosure, a thickness of the conductive oxidation surface ranges from 1 nm to 100 nm.

According to an embodiment of the disclosure, a material of the patterned metal layer includes molybdenum, chrome, aluminum, nickel, copper, or alloy of the same.

The disclosure further provides a method of manufacturing a transistor structure including the following steps. A metal layer is formed on a conductive oxidation layer. A patterning process is performed to the conductive oxidation layer and the metal layer, to define a source electrode, a drain electrode and a patterned conductive oxidation layer on the source electrode and the drain electrode. A gate electrode, an organic semiconductor layer, and a gate insulation layer are formed. The gate insulation layer is disposed between the gate and the organic semiconductor layer. A portion of the organic semiconductor layer is exposed between the source electrode and the drain electrode. The patterned conductive oxidation layer directly contacts with the organic semiconductor layer.

According to an embodiment of the disclosure, the gate electrode is formed on a substrate. The gate insulation layer is formed on the gate and covers the gate electrode and a portion of the substrate. The organic semiconductor layer is formed on the gate insulation layer, and the source electrode and the drain electrode are formed on the organic semiconductor layer.

According to an embodiment of the disclosure, the source electrode and the drain electrode are formed on a substrate and expose a portion of the substrate. The organic semiconductor layer is formed on the source electrode and the drain electrode and covers the portion of the substrate. The gate insulation layer is formed on the organic semiconductor layer and covers the organic semiconductor layer, the source electrode and the drain electrode. The gate is formed on the gate insulation layer.

According to an embodiment of the disclosure, a thickness of the conductive oxidation surface ranges from 1 nm to 100 nm.

According to an embodiment of the disclosure, a material of the metal layer includes molybdenum, chrome, aluminum, nickel, copper, or alloy of the same.

As to the above, the conductive oxidation surface of the patterned metal layer or the conductive oxidation layer directly contacts with the organic semiconductor layer, wherein since the conductive oxidation surface or the conductive oxidation layer has high conductivity, injection efficiency of carriers can be improved, and thus the transistor structure of the disclosure has superior electrical performance.

To make the above features and advantages of the disclosure more comprehensible, several embodiments accompanied with drawings are described in detail as follows.

### BRIEF DESCRIPTION OF THE DRAWINGS

FIG. 1 is a schematic cross-sectional view illustrating a transistor structure according to an embodiment of the disclosure.

FIG. 2A through FIG. 2D are schematic cross-sectional views illustrating a manufacturing method of a transistor structure according to an embodiment of the disclosure.

FIG. 3 is a schematic cross-sectional view illustrating a transistor structure according to another embodiment of the disclosure.

### DESCRIPTION OF EMBODIMENTS

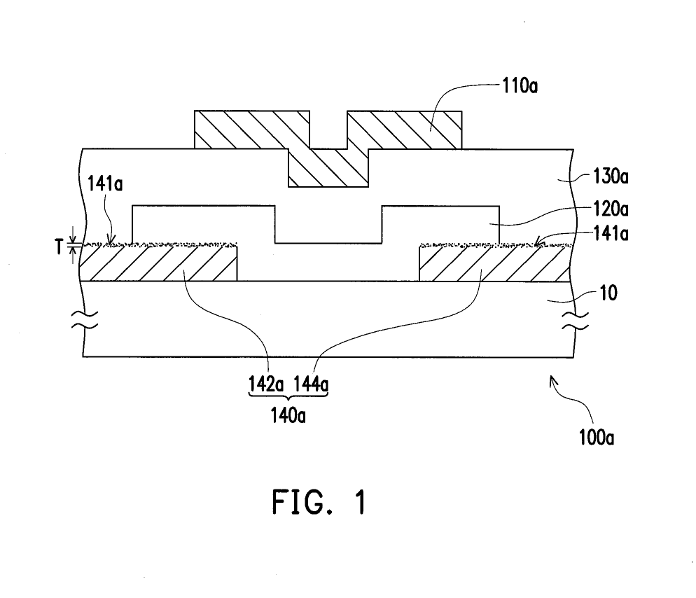

FIG. 1 is a schematic cross-sectional view illustrating a transistor structure according to an embodiment of the disclosure. Referring to FIG. 1, in the present embodiment, the transistor structure 100a is disposed on a substrate 10 and includes a gate electrode 110a, an organic semiconductor layer 120a, a gate insulation layer 130a and a patterned metal layer 140a. The gate insulation layer 130a is disposed between the gate electrode 110a and the organic semiconductor layer 120a. The patterned metal layer 140a has a conductive oxidation surface 141a and is divided into a source electrode 142a and a drain electrode 144a. A portion of the organic semiconductor layer 120a is exposed between the source electrode 142a and the drain electrode 144a. The conductive oxidation surface 141a directly contacts with the organic semiconductor layer 120a.

More specifically, as shown in FIG. 1, the source electrode 142a and the drain electrode 144a of the present embodiment are disposed on the substrate 10 and expose a portion of the substrate 10. The organic semiconductor layer 120a is disposed on the source electrode 142a and the drain electrode 144a and covers the portion of the substrate 10. The gate insulation layer 130a is disposed on the organic semiconductor layer 120a and covers the organic semiconductor layer 120a, the source electrode 142a and the drain electrode 144a. The gate electrode 110a is disposed on the gate insulation layer 130a. To ensure a high reliability of the gate electrode 110a, a passivation layer is provided to cover the gate electrode 110a and the gate insulation layer 130a In brief, the transistor structure 100a of the present embodiment is specifically a top gate transistor structure.

In particular, a material of the patterned metal layer 140a is for example molybdenum, chrome, aluminum, nickel, copper, or alloy of the same. The aforementioned materials have advantage of low cost with respect to the conventional precious metal materials. In addition, the thickness T of the conductive oxidation surface 141a formed by performing an oxidation treatment process to the surface of the patterned metal layer 140a ranges from 1 nm to 100 nm, preferably. Since the conductive oxidation surface 141a of the patterned metal layer 140a of the present embodiment directly contacts with the organic semiconductor layer 120a, the conductive oxidation surface 141a has high conductivity, injection efficiency of carriers can be improved, and thus the transistor structure 100a of the present embodiment has superior electrical performance.

To the manufacturing process, referring to FIG. 1, a surface treatment process is performed to a surface of the patterned metal layer 140a, to form a conductive oxidation surface 141a on the patterned metal layer 140a. The patterned metal layer 140a can be divided into the source electrode 142a and the drain electrode 144a, which are formed on the substrate 10 and expose a portion of the substrate 10. Here, the thickness T of the conductive oxidation surface 141a ranges from 1 nm to 100 nm, preferably. The material of the patterned metal layer 140a is for example molybdenum, chrome, aluminum, nickel, copper, or alloy of the same. The surface treatment process comprises an oxygen-containing plasma treatment process, an oxygen-containing heat treatment process, a chemical oxidation process or an electrochemical oxidation treatment process. The gas utilized in the oxygen-containing heat treatment process is for example nitrous oxide (N₂O), carbon dioxide (CO₂), or oxygen (O₂).

Then, the gate electrode 110a, the organic semiconductor layer 120a, and the gate insulation layer 130a are formed. Please refer to FIG. 1. The organic semiconductor layer 120a is formed on the source electrode 142a and the drain electrode 144a and covers the portion of the substrate 10. The gate insulation layer 130a is formed on the organic semiconductor layer 120a and covers the organic semiconductor layer 120a, the source electrode 142a and the drain electrode 144a. In other words, the gate insulation layer 130a is disposed between the gate electrode 110a and the organic semiconductor layer 120a, a portion of the organic semiconductor layer 120a is exposed between the source electrode 142a and the drain electrode 144a, and the conductive oxidation surface 141a directly contacts the organic semiconductor layer 120a. So far, the transistor structure 100a is completely formed.

The present embodiment adopts lower cost materials such as molybdenum, chrome, aluminum, nickel, copper, or alloy of the same rather than the conventional precious metal materials, and the oxidation treatment process is performed to the surface of the patterned metal layer 140a, to form a conductive oxidation surface 141a having preferable conductivity (i.e. high work function). Therefore, the injection efficiency of carriers of the transistor structure 100a can be improved through the conductive oxidation surface 141a, and thus the transistor structure 100a of the present embodiment has high electrical performance. In addition, the transistor structure 100a of the present embodiment has advantage of low cost.

It is noted that the following embodiments use the reference numerals and part of content of the above embodiment, wherein same reference numbers are used to represent same or similar elements, and repetitive explanation is likely to be omitted. Relevant illustration of the omitted contents can be referred to the foregoing embodiments and is not repeated herein.

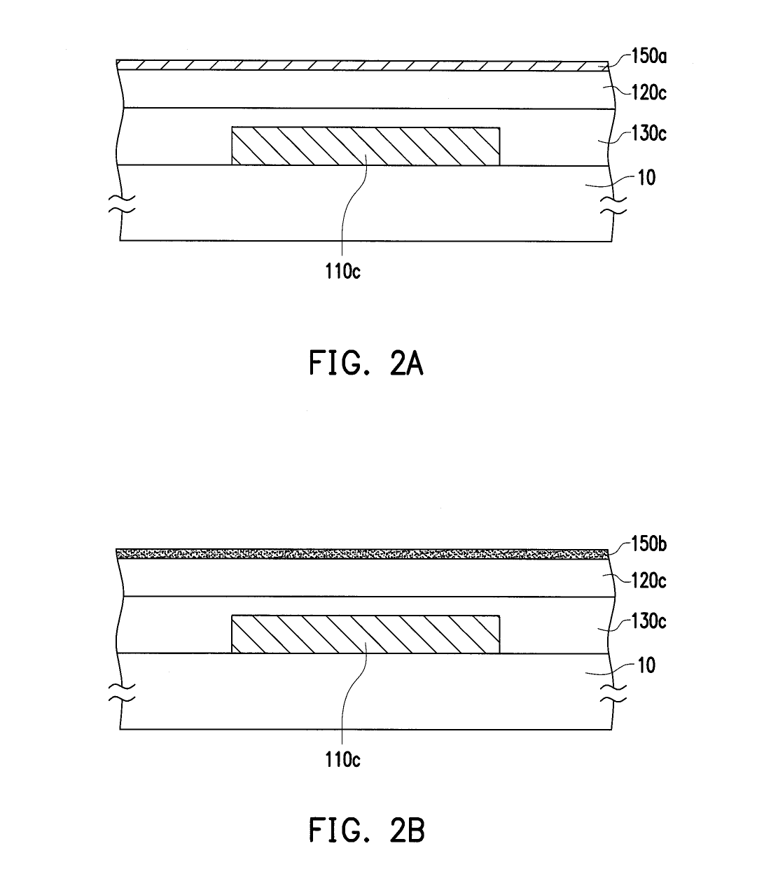

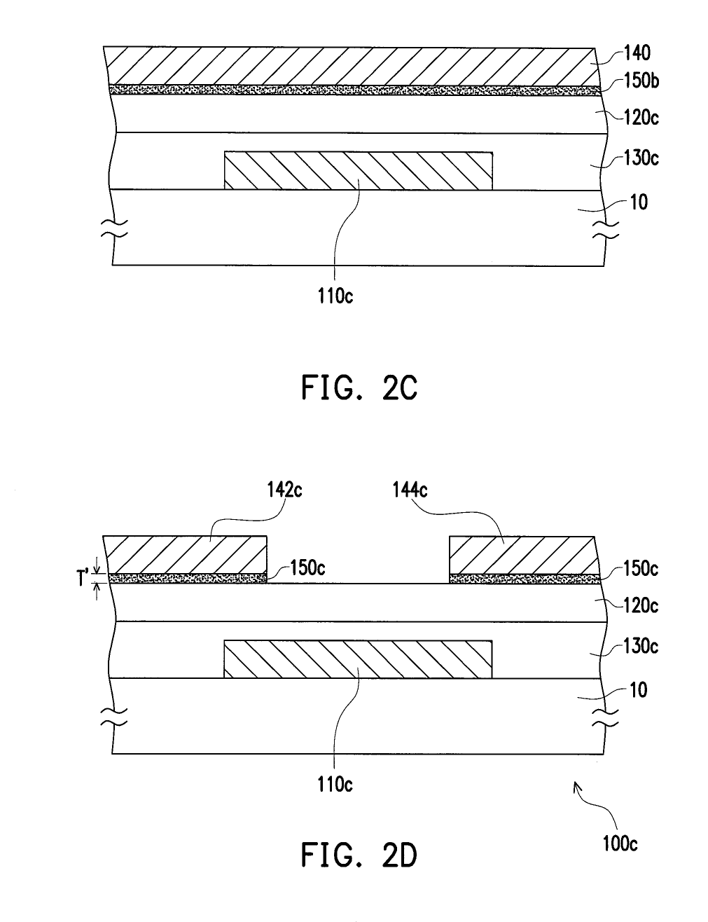

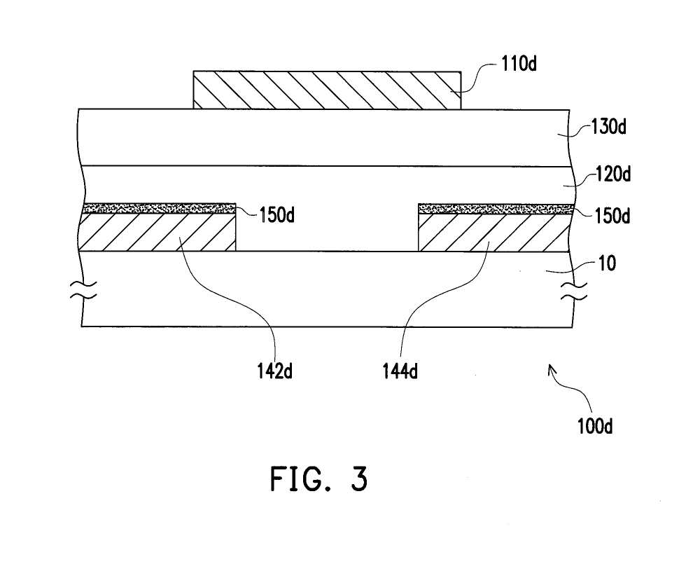

FIG. 2A through FIG. 2D are schematic cross-sectional views illustrating a manufacturing method of a transistor structure according to an embodiment of the disclosure. According to the manufacturing method of the transistor of the present embodiment, firstly, a gate electrode 110c, an organic semiconductor layer 120c and a gate insulation layer 130c are formed. More specifically, the gate electrode 110c is formed on a substrate 10, the gate insulation layer 130c is formed on the gate electrode 110c and covers the gate electrode 110c and a portion of the substrate 10, and the organic semiconductor layer 120c is formed on the gate insulation layer 130c. In other words, the gate insulation layer 130c is disposed between the gate electrode 110c and the organic semiconductor layer 120c.

Then, referring to FIG. 2A and FIG. 2B, a conductive layer 150a is formed on the organic semiconductor layer 120c, and an oxidation treatment process is performed to a surface of the conductive layer 150a, to form a conductive oxidation layer 150b. The oxidation treatment includes, but not limited to, plasma oxidation, thermal oxidation or chemical oxidation.

Then, referring to FIG. 2C, a metal layer 140 is formed on the conductive oxidation layer 150b, wherein the material of the conductive layer 150a can be identical to or different from that of the metal layer 140. In the case of the material of the conductive layer 150a being identical to that of the metal layer 140, the material of the conductive oxidation layer 150b is substantially the same as the oxide of the material of the metal layer 140. Here, the material of the metal layer 140 is for example molybdenum, chrome, aluminum, nickel, copper, or alloy of the same, which has lower cost as compared to the conventional precious metals. In other words, the conductive oxidation layer 150b can be, specifically, molybdenum oxide, chrome oxide, aluminum oxide, copper oxide or alloy oxide of the above metals.

After that, referring to FIG. 2D, a patterning process is performed to the conductive oxidation layer 150b and the metal layer 140, to define a source electrode 142c, a drain electrode 144c and a patterned conductive oxidation layer 150c on the source electrode 142c and the drain electrode 144c. At this moment, the source electrode 142c and the drain electrode 144c are formed on the organic semiconductor layer 120c, a portion of the organic semiconductor layer 120c is exposed between the source electrode 142c and the drain electrode 144c, and the patterned conductive oxidation layer 150c directly contacts with the organic semiconductor layer 120c. Preferably, the thickness T′ of the patterned conductive oxidation layer 150c is for example ranges from 1 nm to 100 nm. So far, the fabrication of the transistor structure 100c is completed, wherein the transistor structure 100c is specifically a bottom gate transistor structure.

FIG. 3 is a schematic cross-sectional view illustrating a transistor structure according to another embodiment of the disclosure. Referring to FIG. 3, the transistor structure 100d of the present embodiment is similar with the transistor structure 100c of FIG. 2D, except that the transistor structure 100d of the present embodiment is a top gate transistor structure. More specifically, firstly, a metal layer (such as the metal layer 140 of FIG. 2C) and a conductive layer (such as the conductive layer 150a of FIG. 2A) are formed on the substrate 10, wherein the conductive layer may be formed by evaporation or sputtering, for example. Then, an oxidation treatment process is performed to the formed conductive layer, to form a conductive oxidation layer (such as the conductive oxidation layer 150b of FIG. 2B). Here, the metal layer is formed on the conductive oxidation layer, and the material of the conductive layer can be substantially identical to or different from that of the metal layer. Then, referring to FIG. 3, a patterning process is performed to the conductive oxidation layer and the metal layer, to define a source electrode 142d, a drain electrode 144d and a patterned conductive oxidation layer 150d on the source electrode 142d and the drain electrode 144d. Next, an organic semiconductor layer 120d, a gate insulation layer 130d and a gate electrode 110d are sequentially formed, wherein the gate insulation layer 130d is disposed between the gate electrode 110d and the organic semiconductor layer 120d, a portion of the organic semiconductor layer 120d is exposed between the source electrode 142d and the drain electrode 144d, and the patterned conductive oxidation layer 150d directly contacts with the organic semiconductor layer 120d. So far, fabrication of the transistor structure 100d is complete.

Accordingly, the conductive oxidation surface of the patterned metal layer or the conductive oxidation layer directly contacts with the organic semiconductor layer, wherein since the conductive oxidation surface or the conductive oxidation layer has high conductivity (i.e. high work function), injection efficiency of carriers can be improved, and thus the transistor structure of the disclosure has superior electrical performance. In addition, the patterned metal layer or the conductive oxidation layer of the disclosure is made of low cost materials such as molybdenum, chrome, aluminum, nickel, copper, or alloy of the same, and thus the transistor structure of the disclosure has the advantage of low cost.

Although the disclosure has been described with reference to the above embodiments, it will be apparent to one of ordinary skill in the art that modifications to the described embodiments may be made without departing from the spirit of the disclosure. Accordingly, the scope of the disclosure will be defined by the attached claims and not by the above detailed descriptions.

What is claimed is:

1. A transistor structure disposed on a substrate and comprising:
a gate electrode;
an organic semiconductor layer;
a gate insulation layer disposed between the gate electrode and the organic semiconductor layer; and
a patterned metal layer having a conductive oxidation surface and divided into a source electrode and a drain electrode, wherein a portion of the organic semiconductor layer is exposed between the source electrode and the drain electrode, and the conductive oxidation surface directly contacts with the organic semiconductor layer.

2. The transistor structure as claimed in claim 1, wherein the source electrode and the drain electrode are disposed on the substrate and expose a portion of the substrate, the organic semiconductor layer is disposed on the source electrode and the drain electrode and covers the portion of the substrate, the gate insulation layer is disposed on the organic semiconductor layer and covers the organic semiconductor layer, the source electrode and the drain electrode, and the gate electrode is disposed on the gate insulation layer.

3. The transistor structure as claimed in claim 1, wherein a material of the patterned metal layer comprises molybdenum, chrome, aluminum, nickel, copper, or alloy of the same.

4. The transistor structure as claimed in claim 1, wherein a thickness of the conductive oxidation surface ranges from 1 nm to 100 nm.

5. A manufacturing method of transistor structure, comprising:
performing a surface treatment process to a surface of a patterned metal layer, to form a conductive oxidation surface on the patterned metal layer, wherein the patterned metal layer is divided into a source electrode and a drain electrode; and
forming a gate electrode, an organic semiconductor layer, and a gate insulation layer, wherein the gate insulation layer is disposed between the gate electrode and the organic semiconductor layer, a portion of the organic semiconductor layer is exposed between the source electrode and the drain electrode, and the conductive oxidation surface directly contacts with the organic semiconductor layer.

6. The manufacturing method of the transistor structure as claimed in claim 5, wherein the surface treatment process comprises an oxygen-containing plasma treatment process, an oxygen-containing heat treatment process, a chemical oxidation process or an electrochemical oxidation treatment process.

7. The manufacturing method of the transistor structure as claimed in claim 5, wherein the source electrode and the drain electrode are formed on a substrate and expose a portion of the substrate, the organic semiconductor layer is formed on the source electrode and the drain electrode and covers the portion of the substrate, the gate insulation layer is formed on the organic semiconductor layer and covers the organic semiconductor layer, the source electrode and the drain electrode, and the gate electrode is formed on the gate insulation layer.

8. The manufacturing method of the transistor structure as claimed in claim 5, wherein a thickness of the conductive oxidation surface ranges from 1 nm to 100 nm.

9. The manufacturing method of the transistor structure as claimed in claim 5, wherein a material of the patterned metal layer comprises molybdenum, chrome, aluminum, nickel, copper, or alloy of the same.

10. A manufacturing method of transistor structure, comprising:
forming a metal layer on a conductive oxidation layer;
performing a patterning process to the conductive oxidation layer and the metal layer, to define a source electrode, a drain electrode and a patterned conductive oxidation layer on the source electrode and the drain electrode; and
forming a gate electrode, an organic semiconductor layer and a gate insulation layer, wherein the gate insulation layer is disposed between the gate electrode and the organic semiconductor layer, a portion of the organic semiconductor layer is exposed between the source electrode and the drain electrode, and the patterned conductive oxidation layer directly contacts with the organic semiconductor layer.

11. The manufacturing method of the transistor structure as claimed in claim 10, wherein the gate electrode is formed on a substrate, the gate insulation layer is formed on the gate and covers the gate electrode and a portion of the substrate, the organic semiconductor layer is formed on the gate insulation layer, and the source electrode and the drain electrode are formed on the organic semiconductor layer.

12. The manufacturing method of the transistor structure as claimed in claim 10, wherein the source electrode and the drain electrode are formed on a substrate and expose a portion of the substrate, the organic semiconductor layer is formed on the source electrode and the drain electrode and covers the portion of the substrate, the gate insulation layer is formed on the organic semiconductor layer and covers the organic semiconductor layer, the source electrode and the drain electrode, and the gate electrode is formed on the gate insulation layer.

13. The manufacturing method of the transistor structure as claimed in claim 10, wherein a thickness of the patterned conductive oxidation layer ranges from 1 nm to 100 nm.

14. The manufacturing method of the transistor structure as claimed in claim 10, wherein a material of the metal layer comprises molybdenum, chrome, aluminum, nickel, copper, or alloy of the same.
